(19) United States
(12) Patent Application Publication
(10) Pub. No.: US 2022/0181555 A1
(43) Pub. Date: Jun. 9, 2022

(54) LIGHT-EMITTING MATERIAL FOR ORGANIC LIGHT-EMITTING DIODE, BLUE LIGHT-EMITTING MATERIAL FOR ORGANIC LIGHT-EMITTING DIODE, AND ORGANIC LIGHT-EMITTING DIODE

(71) Applicants: NATIONAL UNIVERSITY CORPORATION EHIME UNIVERSITY, Matsuyama-shi (JP); FLASK Corporation, Matsuyama-shi (JP)

(72) Inventors: Minoru HAYASHI, Matsuyama-shi (JP); Hidetoshi OHTA, Matsuyama-shi (JP); Hisayuki KAWAMURA, Yonezawa-shi (JP)

(73) Assignees: NATIONAL UNIVERSITY CORPORATION EHIME UNIVERSITY, Matsuyama-shi (JP); FLASK Corporation, Yonezawa-shi, (JP)

(21) Appl. No.: 17/520,878

(22) Filed: Nov. 8, 2021

(30) Foreign Application Priority Data
Dec. 4, 2020 (JP) 2020-201987

(51) Int. Cl. H01L 51/00; C09K 11/06; C09K 11/02; C07F 9/6568

(52) U.S. Cl. CPC H01L 51/0062; C09K 11/06; C09K 11/02; C07F 9/65683; H01L 51/5012; C09K 2211/1022; C09K 2211/1007; C09K 2211/1014; C09K 2211/1018

(57) ABSTRACT

Provided is a blue light-emitting material for organic light-emitting diode (OLED) comprising a phosphinine derivative and the OLED including the same. The light-emitting material for OLED of the present invention comprises the phosphinine derivative having an electron-withdrawing substituent at its C4 position of a phosphorus-containing six-membered ring. The OLED of the present invention has a pair of electrodes and organic layers including light-emitting layers between the pair of the electrodes, wherein the at least one light-emitting layer comprises an anthracene compound and the phosphinine derivative.

### BACKGROUND OF THE INVENTION

### Field of Invention

The present invention relates to a light-emitting material for organic light-emitting diode which emits blue light and the organic light-emitting diode including a light-emitting layer comprising the same.

### Description of the Related Art

When a voltage is applied between a pair of electrodes constituting an organic light-emitting diode (OLED), holes from an anode and electrons from a cathode are injected into a light-emitting layer including organic compounds as luminescence materials, and the injected holes and electrons are recombined. Consequently, excitons are formed in the luminous organic compounds and the excited organic compounds emit luminescence. In other words, the OLED, which is a self-luminous element, is superior in brightness and visibility to the liquid crystal element, and gives us a clear image. The OLED is expected as an outstanding light-emitting element which has high luminous efficiency, high resolution, low power consumption, long lifetime and also flat-screen design, by taking advantage of the self-luminous element.

In order to improve the performance of the OLED, an attempt has been carried out to make an organic light-emitting layer into a host/dopant layer where the host is doped with a luminescence material as a dopant. The organic light-emitting layer made in this way can prevent luminescent excitons from quenching; that is, in a three-layer structure having a hole transport layer, a light-emitting layer and an electron transport layer, the HOMO energy level of the host is made to match that of the hole transport material, and the LUMO of the hole transport layer is raised high enough to transfer holes to the light-emitting layer completely. And the LUMO energy levels of the host and the electron transport layer are also aligned with their interface. Meanwhile, the HOMO of the electron transport layer is made deep enough to confine the charge, and moreover, the energies of triplet excitons of the hole transport material and the electron transport material are raised much higher than the triplet level of the luminescent material. The luminescent excitons are thus prevented from quenching.

The organic light-emitting layer, in which excitons are effectively generated from the charge injected into the host and the energy of the excitons is transferred to the dopant, can obtain high-efficiency luminance from the dopant.

A blue light-emitting dopant is indispensable, because blue is one of three primary colors. But the blue light-emitting dopant has lower luminous efficiency and yet shorter lifetime than those which emit red and green lights, which causes a great demand for the development. A well-known example of such a blue light-emitting dopant is an aromatic amine derivative having unsubstituted pyrene structure bonded with a diarylamino group as disclosed in WO 2006/030527 A1.

An example of an OLED using a phosphinine derivative is disclosed in WO 2011/134577 A1. In this document, phosphinine derivatives having six-membered structure including a N-P-N unit, a P-N-P unit, etc., are used as a host material in the light-emitting layer. NATURE COMMUNICATIONS (2020) 11:4926 discloses that the efficiency roll-off of the OLED using BSBCz as a host and doped with DCNP as a light-emitting material is significantly suppressed even under condition of high current density.

### BRIEF SUMMARY OF THE INVENTION

An object of the present invention is to provide a blue light-emitting material for organic light-emitting diode (OLED) comprising a phosphinine derivative and the OLED including a light-emitting layer comprising the same.

The light-emitting material for OLED according to the present invention is made up of the phosphinine derivative represented by the following general formula (1).

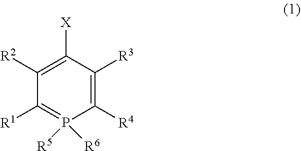

In the general formula (1), X is an electron-withdrawing substituent, R¹ to R⁶ is hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

The blue light-emitting material for OLED according to the present invention is made up of the phosphinine derivative represented by the following general formula (1).

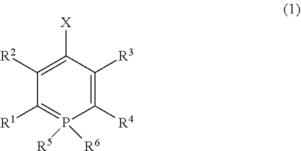

In the general formula (1), X is an electron-withdrawing substituent, R¹ to R⁶ is hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

The organic light-emitting diode according to the present invention has a pair of electrodes and at least one organic light-emitting layer between the pair of the electrodes, wherein the organic light-emitting layer comprises the anthracene derivative represented by the general formula (3) and the phosphinine derivative represented by general formula (2).

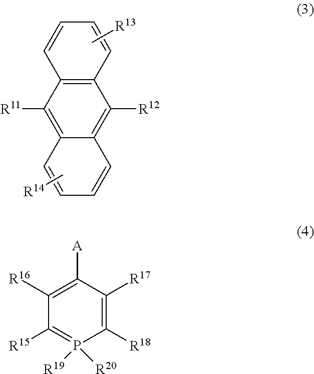

In the general formulae (3) and (2), R¹¹ to R¹⁴, R¹⁵ to R²⁰ and A are hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

Preferably, the organic light-emitting layer comprises an amount of 0.1 to 10 wt % of phosphinine derivative represented by the general formula (2).

The light-emitting material for OLED according to the present invention emits pure blue light required for full color television, so that it is suitably used as blue organic light-emitting material for OLED.

### BRIEF DESCRIPTION OF THE DRAWING

FIG. 1 represents the structure of the OLED of the present invention.

### DESCRIPTION OF THE PREFERRED EMBODIMENTS

The light-emitting material for OLED and the OLED of the present invention will be described in detail.

### [Light-Emitting Material for OLED]

The light-emitting material for OLED according to the present invention is made up of the phosphinine derivative represented by the following general formula (1). The phosphinine derivative is an organic compound constituting a phosphorus-containing six-membered ring. Introducing an electron-withdrawing substituent to the C4 position of the phosphinine derivative makes the emission wavelength shorter than introducing an unsubstituted or electron-donating substituent. The phosphinine derivative is a promising dopant for blue light emission because of its high quantum yield of emission.

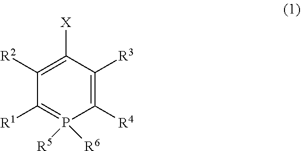

In the general formula (1), X is an electron-withdrawing substituent.

The electron-withdrawing substituent includes cyano group, formyl group, carbonyl group, sulfoxide group, phenylsulfonyl group, sulfone dioxide group, nitro group, phosphine sulfide group, phosphine oxide group, a halogen group, an alkyl halide group, diphenyltriazinyl group, an aryl halide group, trifluoromethyl carbonyl (—C(═O)CF₃) group and diarylphosphonyl (—P(═O)Ar₂) group.

The alkyl halide group includes trifluoromethyl group and trichloromethyl group.

The aryl halide group includes fluorophenyl group, pentafluorophenyl group and hexafluorophenyl group.

The diarylphosphonyl (—P(═O)Ar₂) group includes diphenylphosphonyl group.

R¹ to R⁶ represent hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group and a halogen group.

The alkyl group having 1 to 6 carbon atoms includes methyl group, ethyl group, n-propyl group, isopropyl group, cyclopropyl group, n-butyl group, s-butyl group, t-butyl group,

cyclobutyl group, n-pentyl group, cyclopentyl group, n-hexyl group and cyclohexyl group. The alkyl group may be unsubstituted or substituted.

The alkoxy group having 1 to 6 carbon atoms includes methoxy group, ethoxy group, n-propyloxy group, isopropyloxy group, cyclopropyloxy group, n-butyloxy group, s-butyloxy group, t-butyloxy group, cyclobutyloxy group, n-pentyloxy group, cyclopentyloxy group, n-hexyloxy group and cyclohexyloxy group. The alkoxy group may be unsubstituted or substituted.

The aryl group having 5 to 30 core atoms includes phenyl, deuterated phenyl group, biphenyl group, fluorenyl group, naphthyl group, anthracenyl group, phenanthrenyl group, acenaphthyl group, pyrenyl group, chrysenyl group, triphenylene group, perylenyl group, styryl group, azulenyl group, pyridine group, pyrimidine group, triazine group, quinoline group, quinoxalinyl group, pyrrole group, indole group, 9H-carbazol-9-yl group, acridine group, 9,10-dihydro-9,9-dimethylacridin-10-yl group, phenoxazine group, phenothiazine group, phenazine group, phenazasiline group, phenazaborin group, furan group, benzofuran group, dibenzofuran group, naphthobenzofuran group, thiophene group, benzothiophene group, dibenzothiophene group, silole group, benzosilole group, dibenzosilole group, oxazole group, oxadiazole group, thiazole group, benzothiazole group, imidazole group, benzimidazole group, dioxin group, benzodioxin group, dibenzodioxin group, benzodithiane group, thianthrene group, bis(3,5-di(trifluoromethyl)phenyl group, 4-(1-naphthyl)phenyl group, and 4-phenylnaphthalen-1-yl group. The aryl group may be unsubstituted or substituted. For example, a condensed heterocyclic group having silicon or boron and a substituent bonded with two or more aryl groups are given.

The silyl group includes substituted or unsubstituted triphenylsilyl group.

The amino group includes diethylamino group, diphenylamino group, phenylnaphthylamino group, and dinaphthylamino group. The amino group may be unsubstituted or substituted.

The halogen group includes fluorine, chlorine, bromine and iodine.

Specific examples of the general formula (1) include the following compounds PH1 to PH25, but are not limited thereto as far as the compounds are represented by the general formula (1).

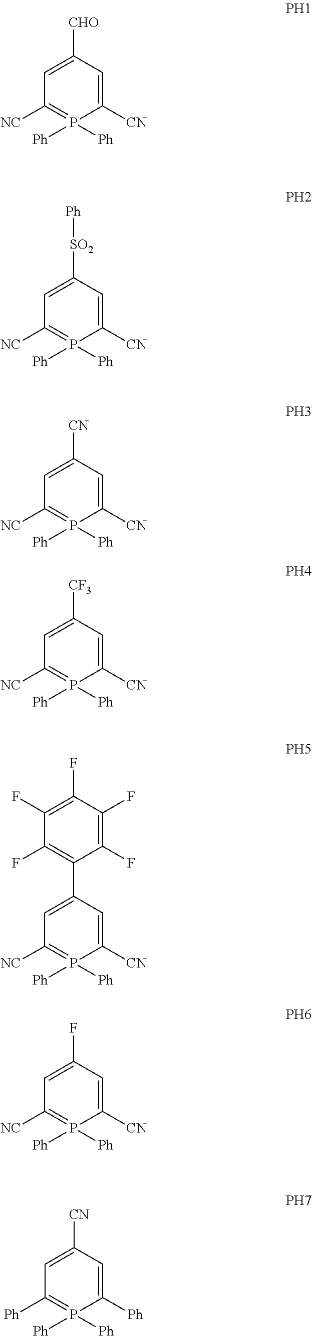

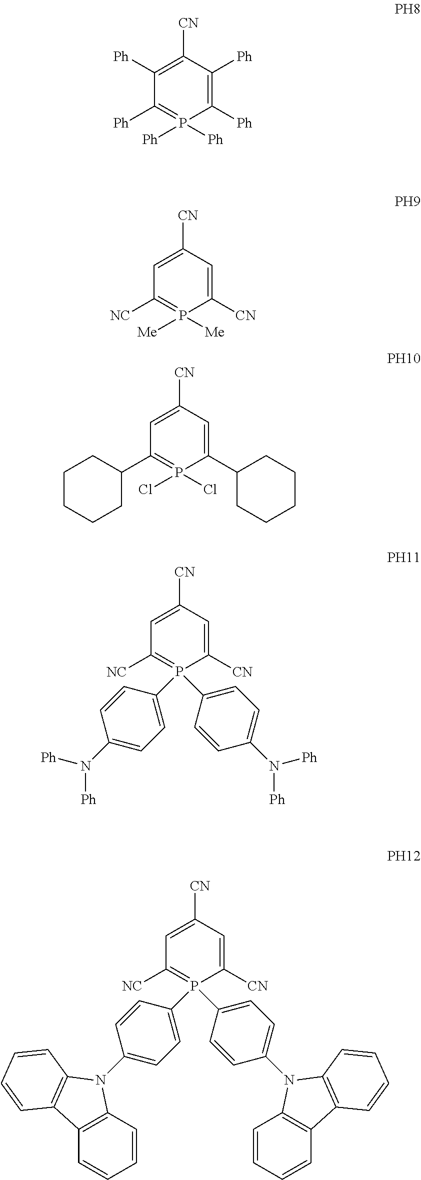

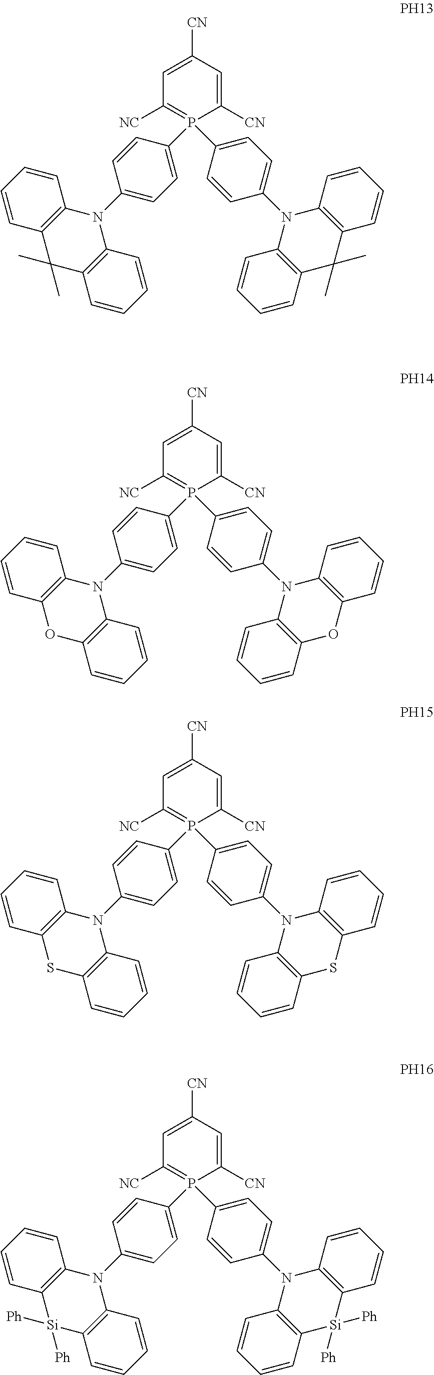

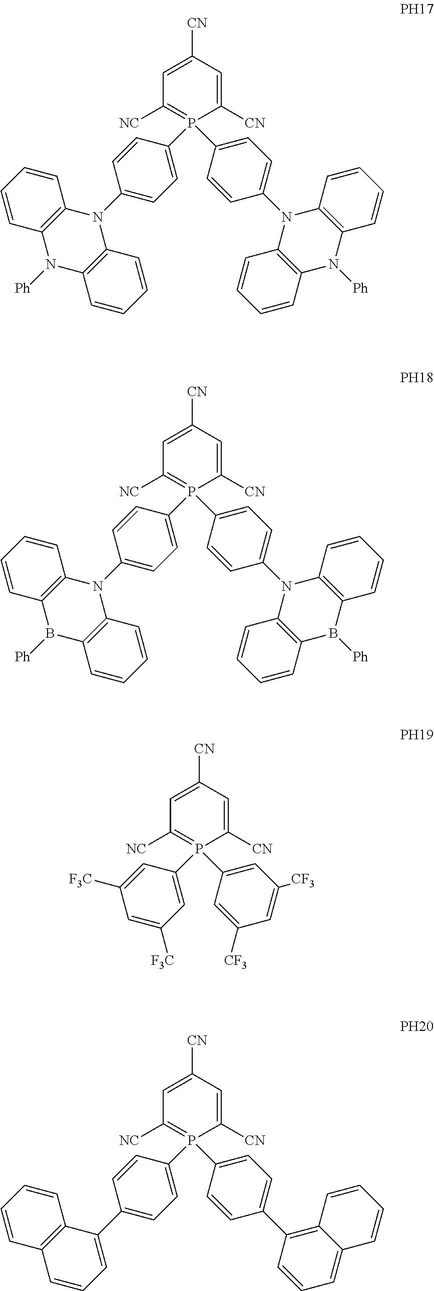

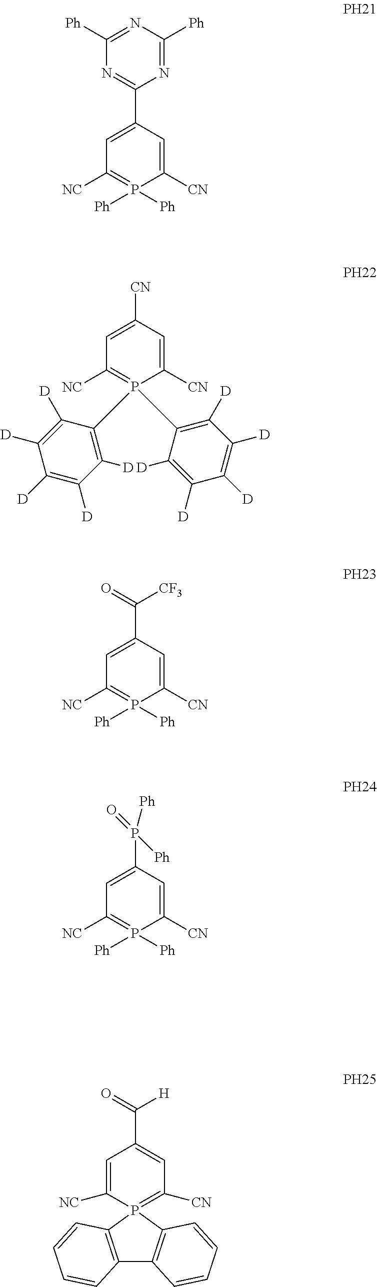

The light-emitting material for OLED of the present invention can be synthesized by various known methods. A method of synthesizing PH1 is shown as one example.

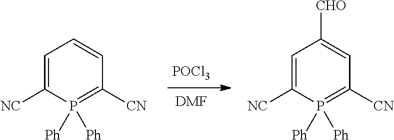

2,6-Dicyano-1,1-diphenyl-λ5σ4-phosphinine (DCNP) is dissolved in N,N-dimethylformamide (DMF), phosphorus oxychloride (POCl₃) is added thereto, and the mixture is stirred at 60° C. for 3 hours until the reaction is stopped. After extraction and purification, the reaction product is recrystallized to give yellow crystals of PH1 in a yield of 84%.

### [Organic Light-Emitting Diode]

The organic light-emitting diode (OLED) of the present invention has a pair of electrodes consisting of anode 2 and cathode 7 and at least one organic layer including an organic light-emitting layer 5 between the pair of the electrodes. The organic light-emitting layer 5 comprises an anthracene derivative represented by the general formula (3) and a phosphinine derivative represented by the general formula (2).

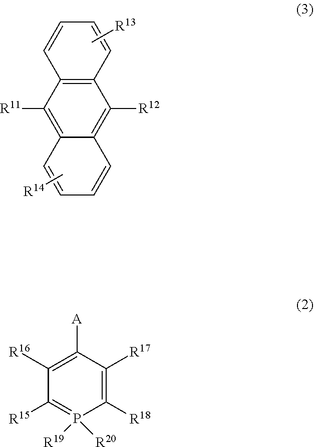

In the general formulae (3) and (2), R¹¹ to R¹⁴, R¹⁶ to R²⁰ and A are hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

Detailed explanation of R¹¹ to R¹⁴, R¹⁶ to R²⁰ and A follow the definition of R¹ to R⁶ in the general formula (1).

A specific example of the general formula (3) includes the following compounds (3-1) to (3-20), but is not limited thereto.

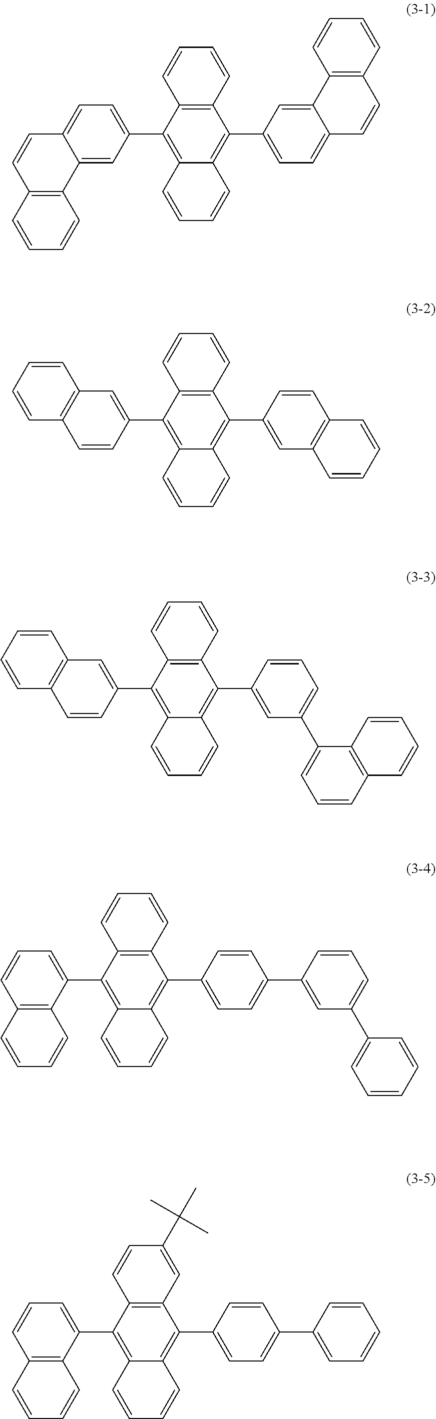

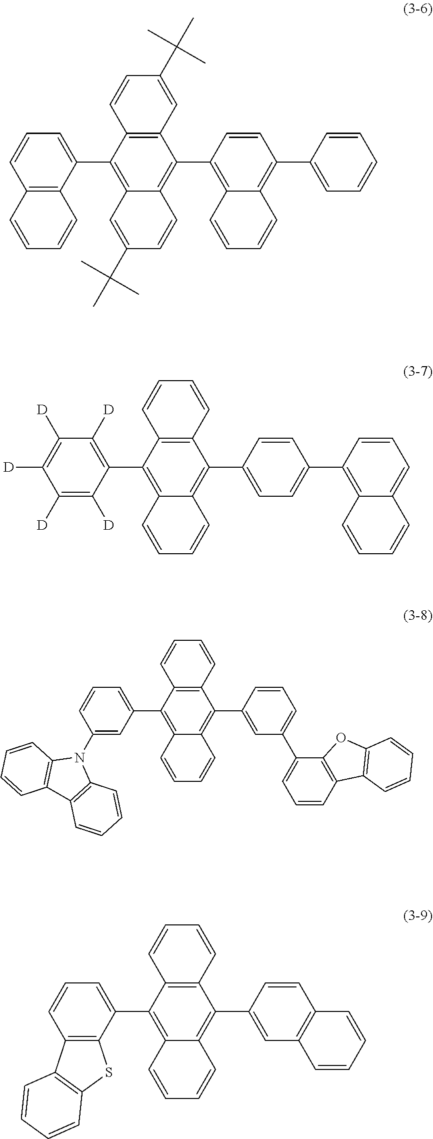

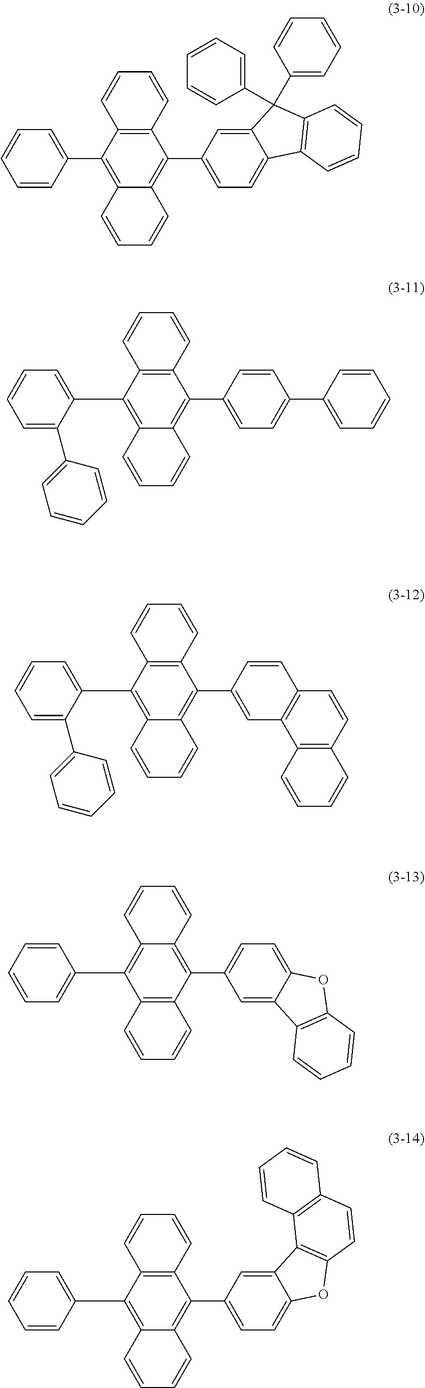

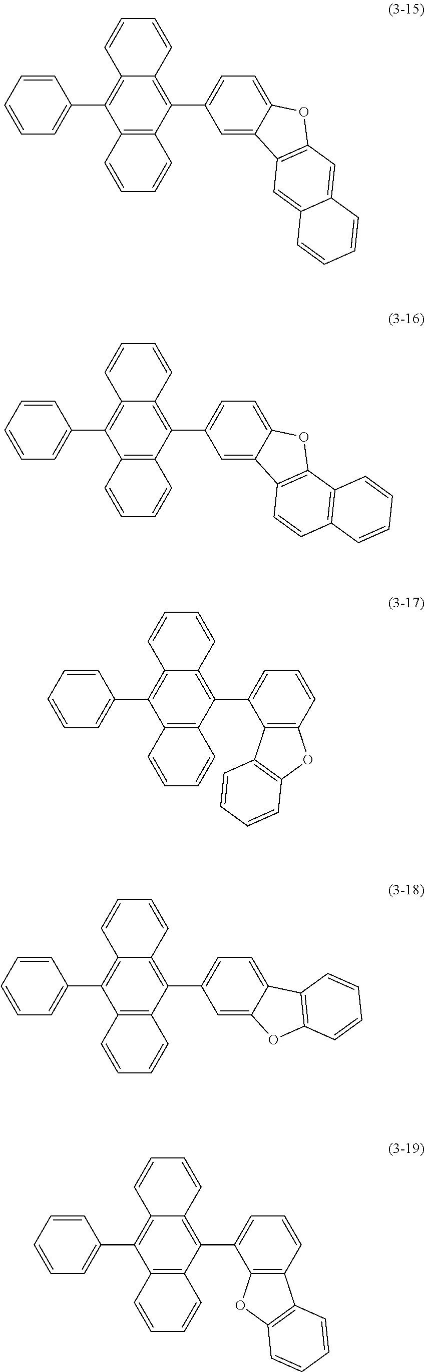

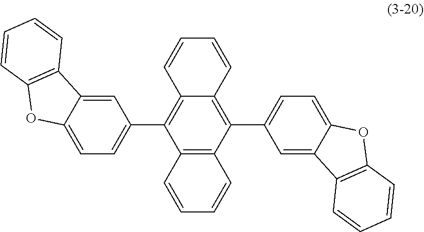

A specific example of the general formula (2) includes the following compounds (Ph-1) to (Ph-13) besides the specific examples indicated in the general formula (1), but is not limited thereto.

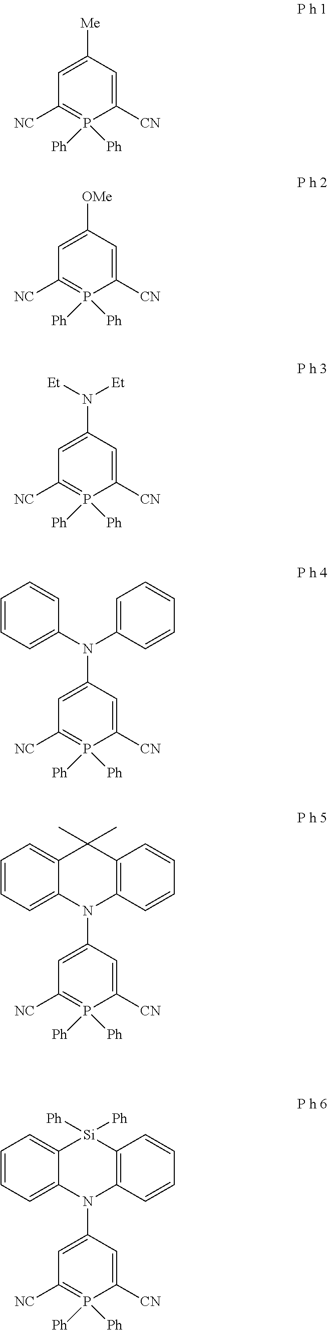

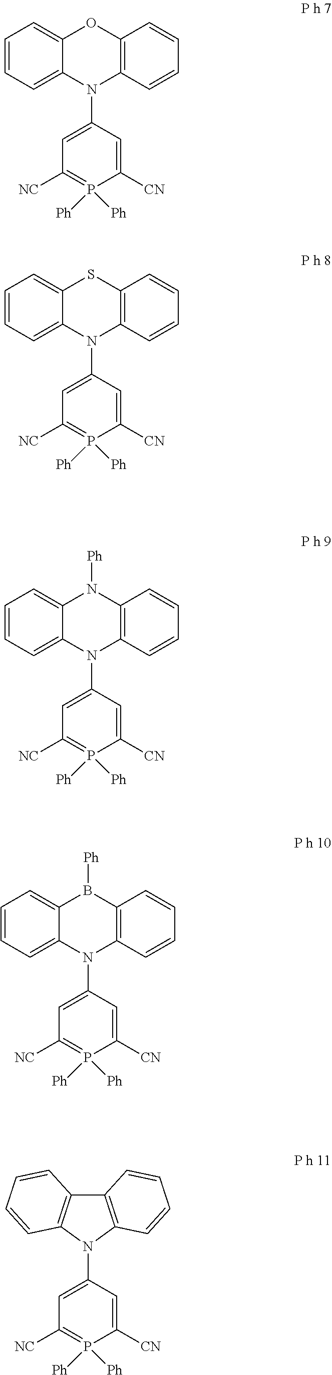

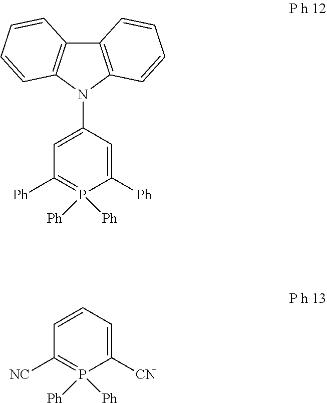

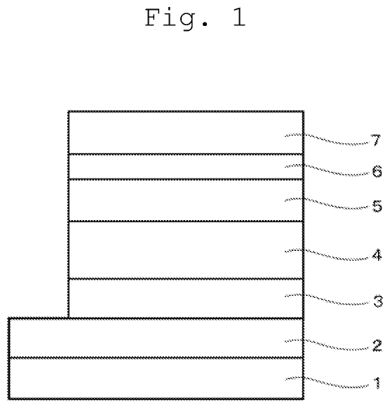

The typical OLED has such a layered structure on the substrate 1 as to deposit an anode 2 (e.g., indium tin oxide (ITO)) and thereon a hole injection layer 3, a hole transport layer 4, an electron blocking layer, an organic light-emitting layer 5, a hole blocking layer, an electron transport layer 6, an electron injection layer and a cathode 7 in this order. Some layers may be omitted in this multi-layer structure. For example, the electron injection layer may be an electron injection and transport layer which also functions as the electron transport layer 6. FIG. 1 is an embodiment of the present invention, and represents the OLED in which hexaazatriphenylenecarbonitrile (HAT-CN) with a thickness of 5 nm as the hole injection layer 3, 4,4′-bis[phenyl(1-naphthyl)amino]biphenyl (NPB) with a thickness of 60 nm as the hole transport layer 4, 9-(dibenzofuran-2-yl)-10-phenylanthracene (BH1) and the phosphinine derivative (4 wt %) of the present invention with a thickness of 30 nm as the organic light-emitting layer 5, 2,9-di(2-naphthyl)-4,7-diphenyl-1,10-phenanthroline (ET1) with a thickness of 20 nm as the electron transport layer 6, and aluminum with a thickness of 100 nm as the cathode 7 are layered on the ITO transparent electrode 2.

Transparent and smooth materials having a total light transmittance of at least 70% or more are used for the substrate 1. To be more concrete, the substrate includes flexible transparent substrate, such as glass substrate having a thickness of several micrometers or special transparent plastic.

The anode 2 is an electrode with a function to inject holes into the hole injection layer 3, the hole transport layer 4 and the organic light-emitting layer 5. Generally, materials for anode 2 include metal oxides, metals, alloys and conductive materials having a work function of 4.5 eV or more, while from the viewpoint of transmitting the emitted light, the materials having a total light transmittance of 80% or more are usually appropriate. To be specific, transparent conductive ceramics such as ITO and zinc oxide (ZnO), transparent conductive materials such as poly(3,4-ethylenedioxythiophene)/poly(4-styrene sulfonic acid) (PEDOT-PSS) and polyaniline are used. The anode 2 usually has a thickness of 5 to 500 nm and preferably 10 to 200 nm.

The anode 2 is formed by vapor deposition method, electron beam method, sputtering method, chemical reaction method, and coating method.

The cathode 7 is an electrode with a function to inject electrons into the electron transport layer 6 and the organic light-emitting layer 5. Generally, metals and alloys having a work function of approximately 4 eV or less are appropriate for the cathode 7 materials. Metals used as the cathode 7 include aluminum, lithium, sodium, potassium, calcium and magnesium. An example of the cathode made of an alloy is an electrode of an alloy of the foregoing low-work function metal and metals such as aluminum and silver, or a layer-structured electrode composed of the low-work function metal and metals such as aluminum and silver. The cathode 7 usually has a thickness of 10 to 200 nm.

The cathode 7 is formed by vapor deposition method, electron beam method, sputtering method, chemical reaction method, and coating method.

The hole injection layer 3 is a layer introduced to improve the luminous efficiency. To supply the current at low voltage, the hole injection layer 3 should be 1 to 20 nm-thick, which means thin enough not to cause pinholes, and yet uniform. The hole injection material includes triphenylamine-containing polymer: (4-isopropyl-4′-methyldiphenyliodonium tetrakis(pentafluorophenyl)borate (KLHIP:PPBI), triphenylamine-containing polyether ketone (TPAPEK), hexaazatriphenylenecarbonitrile (HAT-CN), poly(3,4-ethylenedioxythiophene) (PEDOT:PSS), phenylamine type, starburst type amine, poly(ether ketones) (PEK) and polyaniline.

The hole transport layer 4 which is placed between the anode 2 and the organic light-emitting layer 5, works for transporting holes from the anode 2 to the organic light-emitting layer 5 efficiently. The material having a small ionization potential, that is to say, the material which easily excites electrons from the HOMO and generates holes is used as the hole transport material. Specific examples include 4,4′-bis[phenyl(1-naphthyl)amino]biphenyl (NPB), hexaphenylbenzene derivative (4DBTHPB), poly(9,9-dioctylfluorene-alt-N-(4-butylphenyl)diphenylamine) (TFB), 4,4′-cyclohexylidenebis[N,N-bis(4-methylphenyl)benzenamine] (TAPC), N,N′-diphenyl-N,N′-di(m-tolyl)benzidine (TPD), 4,4′,4″-tri-9-carbazolyltriphenylamine (TCTA) and 4,4′,4″-tris[phenyl(m-tolyl)amino]triphenylamine.

The electron blocking layer which is placed between the hole transport layer 4 and the organic light-emitting layer 5, has a role of preventing electrons from passing through the organic light-emitting layer 5 toward the hole transport layer 4. The electron blocking layer and the hole transport layer described later also serve as an exciton blocking layer.

The organic light-emitting layer 5 comprises a dopant and a host. The anthracene derivative represented by the general formula (3) is used as a host. There is no particular restriction to other host materials which can be used together, provided that the host materials minimize charge injection barrier from the hole transport layer 4 and the electron transport layer 6, confine the charge within the organic light-emitting layer 5, and prevent the luminescence excitons from quenching. For example, a distyrylarylene derivative, an oxadiazole derivative, a polyvinyl carbazole derivative, a polyparaphenylene derivative, 9,9′-diphenyl-9H,9′H-3,3′-dicarbazole (BCzPh), bis[2-(diphenylphosphino)phenyl] ether oxide (DPEPO), 3,6-bis(diphenylphosphoryl)-9-phenylcarbazole (PO9), 4,4′-bis(N-carbazolyl)-1,1′-biphenyl (CBP), 3,3′-bis(N-carbazolyl)-1,1′-biphenyl (mCBP), tris(4-carbazoyl-9-ylphenyl)amine (TCTA), 2,8-bis(diphenylphosphoryl)dibenzothiophene (PPT), adamantane-anthracene (Ad-Ant), rubrene, 2,2′-bi(9,10-diphenylanthracene) (TPBA) and 1,4-di(1,10-phenanthrolin-2-yl)benzene (DPB) are given.

The phosphinine derivative represented by the general formula (2) is used as the dopants. Other dopants which can be used together with the phosphinine derivative include perylene derivatives, coumarin derivatives, rubrene derivatives, quinacridone derivatives, squarylium derivatives, porphyrin derivatives, styryl pigments, tetracene derivatives, pyrazolone derivatives, decacyclene and phenoxazone.

The amount of dopant is approximately 0.1 to 10 wt % and preferably 0.5 to 5 wt % of the total amount of the host and the dopant.

The hole blocking layer which is placed between the organic light-emitting layer 5 and the electron transport layer 6, has a role of enhancing the probability of recombining electrons with holes in the organic light-emitting layer 5 while transporting the electrons with the holes being kept away from the electron transport layer 6. The hole blocking material includes 2-(3′-(dibenzo[b,d]thiophen-4-yl)-[1,1′-biphenyl]-3-yl)-4,6-diphenyl-1,3,5-triazine (DBT-TRZ), phenanthroline derivatives such as bathocuproine (BCP), metal complexes of quinolinol derivatives such as aluminum(III) bis(2-methyl-8-quinolinato)-4-phenylphenolate (BAlq), various rare earth complexes, oxazole derivatives, triazole derivatives, triazine derivatives, pyrimidine derivatives, oxadiazole derivatives, and benzazole derivatives. These materials can be also used as the materials for the electron transport layer 6.

The electron transport layer 6 which is placed between the cathode 7 and the organic light-emitting layer 5, has a role of transporting electrons from the cathode 7 to the organic light-emitting layer 5 efficiently. The electron transport materials which have high electron affinity, in other words, the materials which make the energy level of the LUMO lower and make the electrons easily excited are available. Examples include 2,9-di(2-naphthyl)-4,7-diphenyl-1,10-phenanthroline (ET1), 3,3″,5,5′-tetra(3-pyridyl)-1,1′;3′,1″-terphenyl (B3PyPB), 4,6-bis(3,5-di(pyridin-3-yl)phenyl)-2-methylpyrimidine (B3PyMPM), 2-(4-biphenylyl)-5-(p-t-butylphenyl)-1,3,4-oxadiazole (tBu-PBD), 1,3-bis[5-(4-t-butylphenyl)-2-[1,3,4]oxadiazolyl]benzene (OXD-7), 3-(biphenyl-4-yl)-5-(4-t-butylphenyl)-4-phenyl-4H-1,2,4-triazole (TAZ), bathocuproine (BCP), and 1,3,5-tris(1-phenyl-1H-benzimidazol-2-yl)benzene (TPBi).

The electron injection layer which is in contact with the cathode 7 has a role of transporting electrons. The electron injection material includes lithium fluoride (LiF), 8-hydroxyquinolinolato-lithium (Liq), and lithium 2-(2′,2″-bipyridin-6′-yl)phenolate (Libpp).

Thin films formed on the substrate 1, such as the hole injection layer 3, the hole transport layer 4, the organic light-emitting layer 5, the electron transport layer 6 and the electron injection layer are layered by vacuum deposition methods or coating methods.

The vacuum deposition methods include resistance heating evaporation method, electronic beam evaporation method, sputtering method, and molecular layer method. In a case where the vacuum deposition method is applied, a vapor deposition substance is usually heated from 300 to 400° C. in an atmosphere of a reduced pressure to 10⁻³ Pa or less.

In a case where the coating method is applied, materials for each layer are dissolved in chloroform, methylene chloride, dichloroethane, tetrahydrofuran, toluene, xylene, acetone, methyl ethyl ketone, ethyl acetate, butyl acetate, ethyl cellosolve acetate, water and so on, and then each layer is formed by a known coating method. The coating methods include bar coating method, capillary coating method, slit coating method, ink-jet coating method, spray coat method, nozzle coat method, and printing method. Each layer may be formed by the same coating method, or severally optimal coating method may be applied according to the type of ink.

Each organic layer between the anode 2 and the cathode 7 usually has a thickness of 1 to 100 nm and preferably 1 to 50 nm, although some differences exist depending on the resistance values and the charge mobility of constituent materials.

Besides the single wafer process, the OLED of the present invention may be manufactured by the roll-to-roll process, for example.

### EXAMPLES

Hereinafter, the present invention will be described in detail with reference to examples, but the present invention is not restricted thereto.

The light-emitting materials for OLED were prepared as shown in Examples 1 to 4.

### [Example 1] Synthesis of PH1

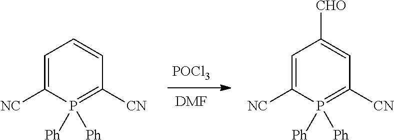

2,6-Dicyano-1,1-diphenyl-λ5σ4-phosphinine (DCNP) was dissolved in N,N-dimethylformamide (DMF), phosphorus oxychloride (POCl₃) was added thereto, and the mixture was reacted at 60° C. for 3 hours. After quenched and neutralized with water, the reaction product was extracted with ethyl acetate 5 times, and the collected organic phase was dried and concentrated. The obtained crude product was purified by silica gel column chromatography and then recrystallized to give yellow crystals of PH1 in a yield of 84%.

¹HNMR (400 MHz, CD₂Cl₂) δ 7.69-7.83 (m, 10H), 8.10 (d, J=27.9 Hz, 2H), 9.25 (d, J=1.2 Hz, 1H);

¹³CNMR (100 MHz, CD₂Cl₂) δ 64.83 (brd, C6), 116.07 (d, J=8.7 Hz, C8), 117.12 (d. J=2.8 Hz, C5), 123.45 (d, J=93.7 Hz, C4×2), 130.40 (d, J=13.4 Hz, C2×4), 133.16 (d, J=11.6 Hz, C3×4), 135.00 (d, J=3.2 Hz, C1×2), 150.14 (br, C7×2), 186.25 (s, C9);

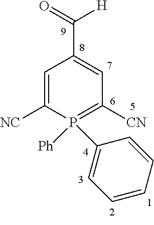 [SMILES: N#CC1=CC(C=O)=CC(C#N)=P1(c1ccccc1)c1ccccc1]

³¹PNMR (162 MHz, CD₂Cl₂) δ 11.6.

mp: 213-216° C.

Anal. Calcd for C₂₀H₁₃N₂OP: C, 73.17; H, 3.99; N, 8.53. Found C, 72.91; H, 3.93; N, 8.39.

HRMS (MALDI-TOF): m/z calcd. for C₂₀H₁₄N₂OP: 329.0838 ([M+H]⁺); found. 329.0847.

### [Example 2] Synthesis of PH2

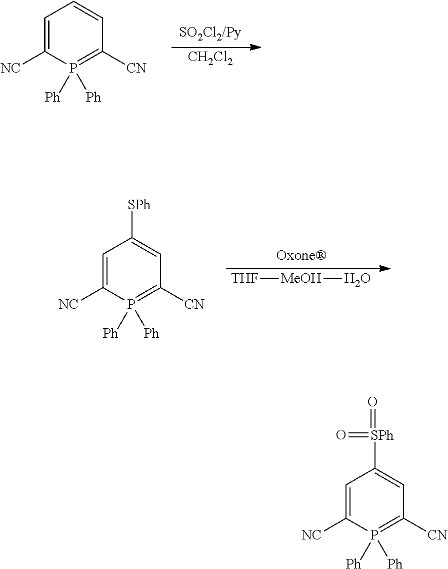

To a dichloromethane solution of diphenyl disulfide, sulfuryl chloride (SO₂Cl₂), pyridine (Py), DCNP and dichloromethane were added and the mixture was stirred at room temperature for 3 hours. After quenched with water, the reaction product was extracted with chloroform, and then the organic phase was washed with 1N hydrochloric acid and saturated brine. The resultant organic phase was dried over sodium sulfate and concentrated. The crude product was purified by silica gel column chromatography to give SPh body as an orange solid in a quantitative yield.

The obtained SPh body was dissolved in a mixed solvent of THF-MeOH—H₂O, potassium peroxymonosulfate (Oxone, registered trademark) was added on ice, and the mixture was reacted at room temperature for 5 hours. After quenched with water, the reaction product was extracted with chloroform, and then the organic phase was washed with saturated brine. The resultant organic phase was dried over sodium sulfate and concentrated. The crude product was purified by silica gel column chromatography to give PH2 as a yellow solid in a yield of 90%.

¹HNMR (400 MHz, CDCl₃) δ 7.50-7.62 (aromatic H, 2H), 7.62-7.67 (aromatic H, 8H), 7.73-7.75 (aromatic H, 2H), 7.83-7.88 (aromatic H, 2H), 8.12 (d, J=26.98 Hz, 2H);

¹³CNMR (100 MHz, CDCl₃) δ 63.07 (d, J=107.8 Hz, 7-C), 115.71 (d, J=9.6 Hz, 5-C), 116.48 (d, J=12.4 Hz, 8-C), 123.0 (d, J=94.02 Hz, 9-C), 126.75 (s, 3-C), 129.39 (s, 2-C), 130.02 (d, J=13.8 Hz, 11-C), 132.68 (d, J=11.67 Hz, 10-C), 132.80 (s, 1-C), 134.61 (d, J=2.99 Hz, 12-C), 142.42 (s, 4-C), 146.95 (d, J=1.84 Hz, 6-C);

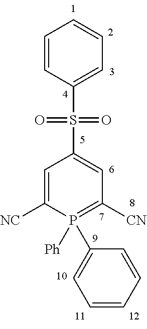 [SMILES: N#CC1=CC(S(=O)(=O)c2ccccc2)=CC(C#N)=P1(c1ccccc1)c1ccccc1]

³¹PNMR (162 MHz, CDCl₃) δ 9.29.

IR (cm⁻¹): 3023, 2197, 1562, 1456, 1329, 1262, 1181, 1147, 1107, 1087, 997, 758.

mp: 253-256° C.

HRMS (FAB): m/z calcd. for C₂₅H₁₇N₂O₂PS: 440.0748 ([M]⁺); found. 440.0756 Matrix: PEG400

### [Example 3] Synthesis of PH3

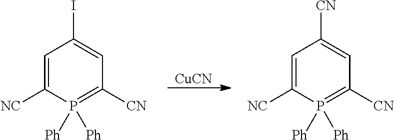

Copper cyanide (I) was added to a DMF solution of iodo-DCNP and the mixture was reacted at 150° C. for 21 hours. After cooling, the reaction product was quenched with water and extracted with chloroform. The organic phase was washed, dried and concentrated, and the crude product was purified by silica gel column chromatography to give PH3 as a yellow solid in a yield of 48%.

¹HNMR (400 MHz, CDCl₃) δ 7.67-7.81 (m, 12H);

¹³CNMR (100 MHz, CDCl₃) δ 64.27 (d, J=106.13 Hz, 6-C×2), 86.90 (d, J=13.14 Hz, 8-C×1), 116.30 (d, J=11.57 Hz, 5-C×2), 118.89 (d, J=1.32 Hz, 9-C×1), 123.06 (d, J=94.42 Hz, 4-C×2), 130.29 (d, J=13.81 Hz, 3-C×4), 132.88 (d, J=11.72 Hz, 2-C×4), 134.92 (d, J=3.25 Hz, 1-C×2), 150.12 (d, J=1.61 Hz, 7-C×2);

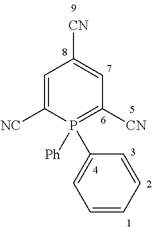 [SMILES: N#CC1=CC(C#N)=P(c2ccccc2)(c2ccccc2)C(C#N)=C1]

³¹PNMR (162 MHz, CDCl₃) δ 8.83.

### [Example 4] Synthesis of PH23

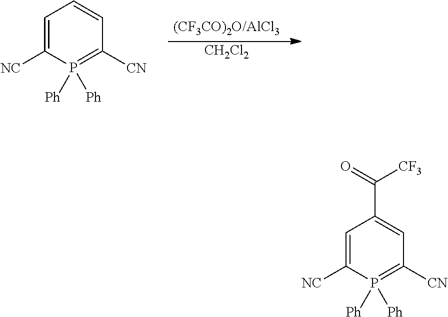 [SMILES: N#CC1=CC=CC(C#N)=P1(c1ccccc1)c1ccccc1 ; "CH2Cl2" ; N#CC1=CC(C(=O)C(F)(F)F)=CC(C#N)=P1(c1ccccc1)c1ccccc1]

To a dichloromethane solution of trifluoroacetic anhydride, aluminum chloride and DCNP were added on ice and the mixture was reacted at room temperature for 2 days. After quenched with water, the reaction product was extracted with chloroform, and then the organic phase was washed, dried and concentrated. The crude product thus obtained was purified by silica gel column chromatography to give PH23 as a yellowish brown solid in a yield of 88%.

¹HNMR (400 MHz, CDCl₃) δ 7.76 (m, 10H), 8.36 (d, J=28.11 Hz, 2H);

¹³CNMR (100 MHz, CDCl₃) δ 66.81 (d, J=105.45 Hz, 6-C×2), 108.09 (d, J=9.73 Hz, 8-C×1), 117.22 (q, J=291.12 Hz, 10-C×1), 116.30 (d, J=12.30 Hz, 5-C×2), 122.06 (d, J=94.35 Hz, 4-C×2), 130.36 (d, J=13.82 Hz, 3-C×4), 132.96 (d, J=11.68 Hz, 2-C×4), 135.10 (d, J=3.00 Hz, 1-C×2), 150.31 (s, 7-C×2), 174.10-175.12 (m, 9-C×1);

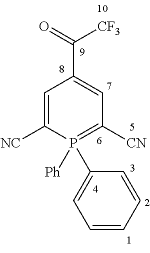 [SMILES: N#CC1=CC(C(=O)C(F)(F)F)=CC(C#N)=P1(c1ccccc1)c1ccccc1]

³¹PNMR (162 MHz, CDCl₃) δ 7.56.

### [Example 5] Manufacturing and Evaluation of the OLED

A glass substrate of 26 mm×28 mm×0.7 mm (manufactured by Opto Science Inc.), on which ITO was sputtered to a thickness of 180 nm and then polished to 150 nm, was used as a transparent support substrate. The transparent support substrate was fixed to a substrate holder of a commercially available deposition apparatus (manufactured by Showa Shinku Co., Ltd.). The deposition apparatus was equipped with a vapor deposition boat made of molybdenum containing hexaazatriphenylenecarbonitrile (HAT-CN), a vapor deposition boat made of molybdenum containing 4,4′-bis[phenyl(1-naphthyl)amino]biphenyl (NPB), a vapor deposition boat made of molybdenum containing BH1, a vapor deposition boat made of molybdenum containing PH1 synthesized in Example 1, a vapor deposition boat made of molybdenum containing 2,9-di(2-naphthyl)-4,7-diphenyl-1,10-phenanthroline (ET1), and a vapor deposition boat made of tungsten containing aluminum.

Each layer was successively formed on the ITO film of the transparent support substrate as described below. The inside pressure of a vacuum chamber was reduced to 5×10⁻⁴ Pa, and first of all, the vapor deposition boat containing HAT-CN was heated, so that HAT-CN could vaporize and form the hole injection layer 3 with a thickness of 5 nm. Next, the vapor deposition boat containing NPB was heated, so that NPB could vaporize and form the hole transport layer 4 with a thickness of 60 nm.

The vapor deposition boat containing BH1 and the vapor deposition boat containing PH1 were heated, so that BH1 and PH1 could simultaneously vaporize and form the organic light-emitting layer 5 with a thickness of 30 nm. The vapor deposion rate of PH1 was adjusted so that PH1 could be contained in the organic light-emitting layer in an amount of 4 wt %.

Next, the vapor deposition boat containing ET1 was heated, so that ET1 could vaporize and form the electron transport layer 6 with a thickness of 20 nm.

The vapor deposion rate of each layer was 1 to 2 nm/s.

Finally, the vapor deposition boat containing aluminum was heated, and the cathode was formed with a thickness of 100 nm at a vapor deposition rate of 0.01 to 2 nm/s, which resulted in the OLED.

When the direct current was applied to the OLED with an ITO electrode as an anode and a LiF/aluminum electrode as a cathode, blue light emission was observed.

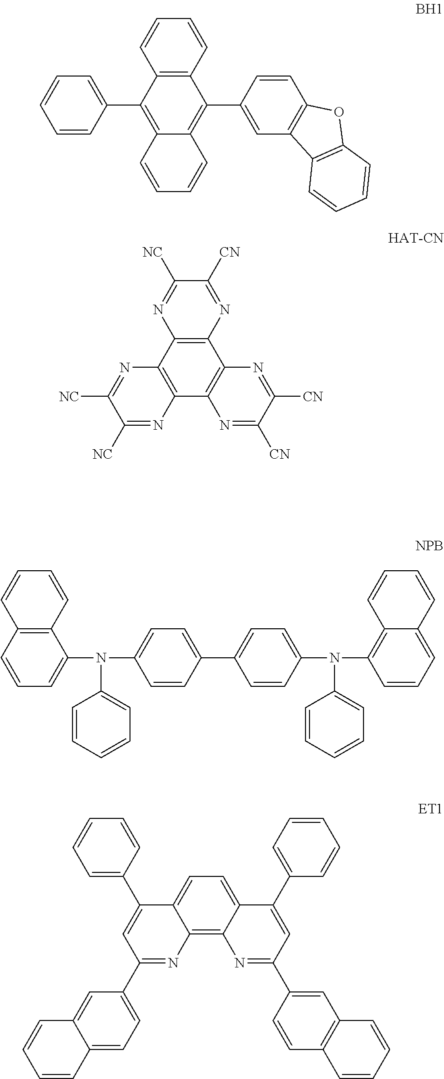 [SMILES: c1ccc(-c2c3ccccc3c(-c3ccc4oc5ccccc5c4c3)c3ccccc23)cc1 ; N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; c1ccc(-c2cc(-c3ccc4ccccc4c3)nc3c2ccc2c(-c4ccccc4)cc(-c4ccc5ccccc5c4)nc23)cc1]

### [Example 6] Manufacturing and Evaluation of the OLED

An elemental device was manufactured in quite a similar manner to Example 5, except that PH2 was used in place of PH1.

### [Comparative Example 1] Manufacturing and Evaluation of the OLED

An elemental device was manufactured in quite a similar manner to Example 5, except that BD1 was used in place of PH1.

### [Comparative Example 2] Manufacturing and Evaluation of the OLED

An elemental device was manufactured in quite a similar manner to Example 5, except that CBP was used in place of BH1.

### [Comparative Example 3] Manufacturing and Evaluation of the OLED

An elemental device was manufactured in quite a similar manner to Example 5, except that BSBCz was used in place of BH1.

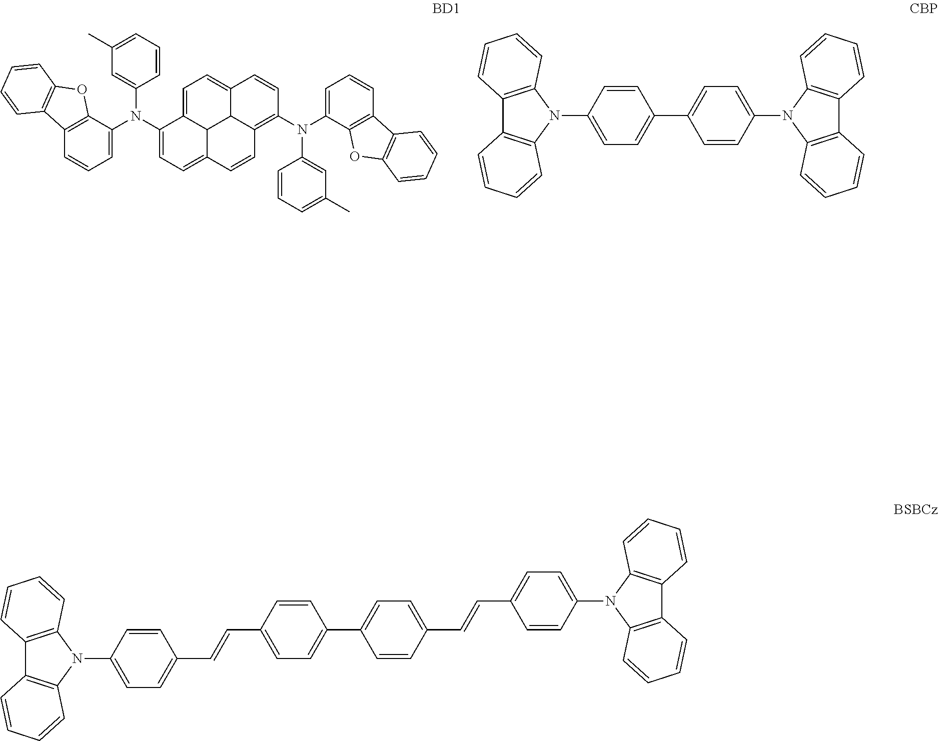

TABLE 1
Light-emitting characteristics when the OLED was
driven at 10 mA/cm²

| | | | Luminous | | |
|---|---|---|---|---|---|
| | Voltage | Luminance | Efficiency | Chromaticity | |
| | (V) | (cd/m²) | (cd/A) | CIE1931 | L/J/y |
| Ex. 5 | 6.1 | 218 | 2.2 | 0.140, 0.196 | 11.2 |
| Ex. 6 | 6.8 | 272 | 2.7 | 0.146, 0.226 | 11.9 |
| Comp. Ex. | 6.0 | 164 | 1.6 | 0.141, 0.184 | 8.7 |
| 1 | | | | | |
| Comp. Ex. | 7.0 | 209 | 2.1 | 0.142, 0.198 | 10.6 |
| 2 | | | | | |
| Comp. Ex. | 6.6 | 183 | 1.8 | 0.141, 0.193 | 9.5 |
| 3 | | | | | |

TABLE 2
Relative value of T95 lifetime measured at initial
luminance of 500 cd/m²

| | LT95 |
|---|---|
| Ex. 5 | 1.3 |
| Ex. 6 | 1.1 |
| Comp. Ex. 1 | 1.0 |
| Comp. Ex. 2 | 0.12 |
| Comp. Ex. 3 | 0.15 |

L/J/y is the luminous efficiency, considering the difference of luminescent chromaticity. The OLED including the phosphinine derivative of the present invention has dominantly higher luminous efficiency than the OLED including aromatic amine-based blue dopants known in the prior art.

As clearly shown in Table 2, the dopant materials using the phosphinine derivative of the present invention significantly improve luminous efficiency when used in combination with the anthracene-based hosts such as BH1, compared with the case used in combination with host materials having no anthracene structure, such as CBP and BSBCz.

As suggested in Table 3, there is a possibility that thermally activated delayed fluorescence is occurring through a higher triplet state to a singlet excited state, which realizes high efficiency luminance.

TABLE 3
Calculation results based on Gaussian09. B3LYP/6-
31G(d)//B3LYP/6-31G(d) level

| | ΔS1 − T1 (eV) | ΔS1 − T2 (eV) | ΔS1 − T3 (eV) |
|---|---|---|---|
| PH1 | 0.79 | −0.26 | −0.41 |
| PH2 | 0.94 | −0.14 | −0.26 |

The OLED including the light-emitting material for OLED of the present invention can give pure blue light emission required for full color television.

What is claimed is:

1. A light-emitting material for organic light-emitting diode comprising a phosphinine derivative represented by the following general formula (1): 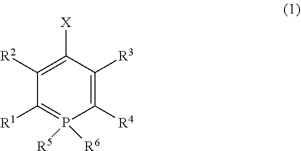
in the general formula (1), X is an electron-withdrawing substituent, R¹ to R⁶ is hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

2. A blue light-emitting material for organic light-emitting diode comprising a phosphinine derivative represented by the following general formula (1): 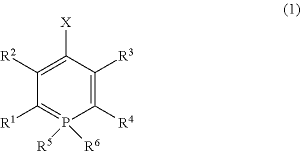
in the general formula (1), X is an electron-withdrawing substituent, R¹ to R⁶ is hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

3. An organic light-emitting diode having a pair of electrodes and at least one organic light-emitting layer sandwiched in between the pair of the electrodes, wherein the organic light-emitting layer comprises an anthracene derivative represented by the general formula (3) and a phosphinine derivative represented by the general formula (2): 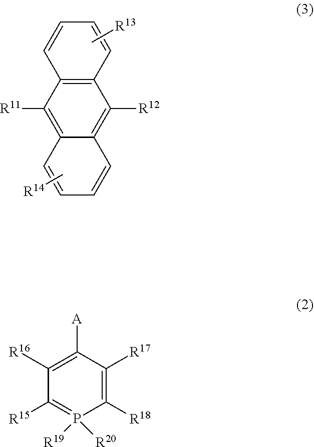
in the general formulae (3) and (2), R¹¹ to R¹⁴, R¹⁵ to R²⁰ and A are hydrogen, deuterium, an alkyl group having 1 to 6 carbon atoms, an alkoxy group having 1 to 6 carbon atoms, an aryl group having 5 to 30 core atoms, silyl group, cyano group, formyl group, carbonyl group, amino group, nitro group, or a halogen group.

4. The organic light-emitting diode according to claim 3, wherein the organic light-emitting layer comprises an amount of 0.1 to 10 wt % of phosphinine derivative represented by the general formula (2).
